(19) United States
(12) Patent Application Publication
(10) Pub. No.: US 2023/0357915 A1
(43) Pub. Date: Nov. 9, 2023

(54) MASK SHEET AND METHOD OF MANUFACTURING DISPLAY APPARATUS

(71) Applicant: Samsung Display Co., Ltd., Yongin-si (KR)

(72) Inventor: Sangha Park, Yongin-si (KR)

(21) Appl. No.: 18/169,801

(22) Filed: Feb. 15, 2023

(30) Foreign Application Priority Data
May 4, 2022 (KR) 10-2022-0055454

(51) Int. Cl. C23C 14/04; H10K 71/16

(52) U.S. Cl. CPC C23C 14/042; H10K 71/166

(57) ABSTRACT

A mask sheet has: a deposition area; clamping areas spaced apart from each other in a first direction with the deposition area therebetween; and a welding area between each of the clamping areas and the deposition area. Each of the clamping areas includes: a body portion having a first side spaced apart from the welding area in the first direction and a second side connected to each of both sides of the first side to cross the first side; a first clamping portion protruding from the first side; and a second clamping portion protruding from the second side.

### CROSS-REFERENCE TO RELATED APPLICATION

This application claims priority to and the benefit of Korean Patent Application No. 10-2022-0055454, filed on May 4, 2022, in the Korean Intellectual Property Office, the present disclosure of which is incorporated by reference herein in its entirety.

### BACKGROUND

### 1. Field

Aspects of embodiments of the present disclosure relate to a mask sheet and a method of manufacturing a display apparatus.

### 2. Description of the Related Art

Electronic devices are in wide use. Electronic devices have been variously used in mobile electronic devices and stationary electronic devices. Electronic devices include display apparatuses that may provide users with visual information, such as images or videos, to support various functions.

A display apparatus that visually displays data may be formed by depositing various layers, such as an organic layer, a metal layer, and the like. A deposition material may be deposited to form a plurality of layers of the display apparatus. For example, the deposition material is ejected from a deposition source and deposited on a substrate through a mask assembly. When the mask sheet and/or a mask frame to which the mask sheet is welded deforms, the deposition material is not deposited at a desired position on the substrate, and thus, deposition quality degrades.

The above-described background technology is information that the inventor possessed for the derivation of the present disclosure or acquired in the process of deriving the present disclosure, and it cannot be said that it is known technology disclosed to the general public before the filing of the present disclosure. Thus, the above background technology may not form prior art.

### SUMMARY

One or more embodiments of the present disclosure include a mask sheet that may improve deposition quality of a deposition material by improving (or reducing) waves generated in the mask sheet when the mask sheet is tensioned, and a method of manufacturing a display apparatus.

However, the above aspects and features are merely examples, and the aspects and features of the present disclosure are not limited thereto.

Additional aspects and features will be set forth, in part, in the description which follows and, in part, will be apparent from the description or may be learned by practice of the described embodiments of the present disclosure.

According to an embodiment of the present disclosure, a mask sheet has a deposition area, clamping areas spaced apart from each other in a first direction with the deposition area therebetween, and a welding area between each of the clamping areas and the deposition area. Each of the clamping areas includes a body portion having a first side spaced apart from the welding area in the first direction and a second side connected to each of both sides of the first side to cross the first direction, a first clamping portion protruding from the first side, and a second clamping portion protruding from the second side.

In an embodiment, a protrusion direction of the second clamping portion may be perpendicular to a protrusion direction of the first clamping portion.

In an embodiment, a protrusion direction of the second clamping portion may have an inclination that is greater than 0° and less than 90° with respect to a protrusion direction of the first clamping portion.

In an embodiment, in a plan view, a maximum width of the mask sheet in the clamping areas may be greater than a maximum width of the mask sheet in the deposition area.

In an embodiment, a protrusion length of the second clamping portion may be equal to a protrusion length of the first clamping portion.

In an embodiment, the first clamping portion and the second clamping portion may be connected to each other in a rounded manner.

In an embodiment, the first clamping portion may include a plurality of first clamping portions arranged along the first side, and a protrusion direction of ones of the first clamping portion nearest each of both end portions of the first side from among the first clamping portions may have an inclination with respect to a protrusion direction of one of the other first clamping portions.

In an embodiment, the second clamping portion may include a plurality of second clamping portions arranged along the second side, and protrusion lengths of the second clamping portions may be different from each other.

In an embodiment, a protrusion length of respective ones of the second clamping portions may increase the nearer the second clamping portions is to the welding area.

In an embodiment, differences in protrusion lengths between two adjacent ones of the second clamping portions from among the second clamping portions may be constant.

In an embodiment, protrusion directions of the second clamping portions may be identical to each other.

In an embodiment, the mask sheet may also have a cutting area between the welding area and the clamping area.

According to another embodiment of the present disclosure, a method of manufacturing a display apparatus includes preparing a mask frame having an opening area, arranging a mask sheet extending in a first direction over the opening area in the mask frame, tensioning the mask sheet in the first direction, welding the mask sheet to the mask frame, arranging a display substrate to face the mask sheet, and allowing a deposition material supplied from a deposition source to pass through the mask sheet to be deposited on the display substrate. The mask sheet includes a first clamping portion protruding from each of both end portions of the mask sheet in the first direction and a second clamping portion protruding in a direction crossing the first direction, and the tensioning of the mask sheet includes tensioning the first clamping portion and the second clamping portion in the first direction.

In an embodiment, the arranging of the mask sheet may include arranging the first clamping portion and the second clamping portion outside an area of the mask frame to where the mask sheet is to be welded in directions of both end portions of the mask sheet.

In an embodiment, the tensioning of the mask sheet may include tensioning the second clamping portion in a direction crossing a protrusion direction of the second clamping portion.

In an embodiment, the tensioning of the mask sheet may include tensioning the second clamping portion in a direction perpendicular to a protrusion direction of the second clamping portion.

In an embodiment, the second clamping portion may include a plurality of second clamping portions in the first direction, and protrusion lengths of the second clamping portions may be different from each other.

In an embodiment, protrusion directions of the second clamping portions may be identical to each other.

In an embodiment, the method may further include cutting both end portions of the mask sheet to remove the first clamping portion and the second clamping portion.

In an embodiment, the mask sheet may include a first mask sheet and a second mask sheet, and the welding and cutting of the mask sheet may include, after the first mask sheet is welded to the mask frame and both end portions of the first mask sheet are cut off, welding the second mask sheet to the mask frame and cutting both end portions of the second mask sheet.

Other aspects and features than those described above will become apparent from the following drawings, claims, and detailed description that form the present disclosure.

### BRIEF DESCRIPTION OF THE DRAWINGS

The above and other aspects and features, of the present disclosure will be more apparent from the following description taken in conjunction with the accompanying drawings, in which:

FIG. 1 is a cross-sectional view of an apparatus for manufacturing a display apparatus according to an embodiment;

FIG. 2 is a schematic perspective view of a mask assembly according to an embodiment;

FIG. 3 is a schematic plan view of a mask sheet according to an embodiment;

FIGS. 4 and 5 are schematic diagrams of a method of manufacturing a display apparatus according to an embodiment;

FIG. 6 is a schematic plan view of a mask sheet according to another embodiment;

FIGS. 7 and 8 are schematic diagrams of a mask sheet according to another embodiment;

FIGS. 9 and 10 are schematic plan views of a mask sheet according to another embodiment;

FIG. 11 is a schematic plan view of a display apparatus manufactured by a method of manufacturing a display apparatus according to an embodiment; and

FIG. 12 is a schematic cross-sectional view taken along the line XII-XII′ of FIG. 11.

### DETAILED DESCRIPTION

Reference will now be made in detail to embodiments, examples of which are illustrated in the accompanying drawings. In this regard, the illustrated embodiments may have different forms and should not be construed as being limited to the descriptions set forth herein. Accordingly, the embodiments are merely described below, by referring to the figures, to explain aspects of the present description.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof. Various modifications may be made to the presented embodiments. The aspects and features of the presented embodiments, and methods to achieve the same, will be clearer referring to the detailed descriptions below with the drawings. However, the present disclosure may be implemented in various forms and is not limited to the embodiments described below.

In the following embodiment, the x-axis, the y-axis, and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

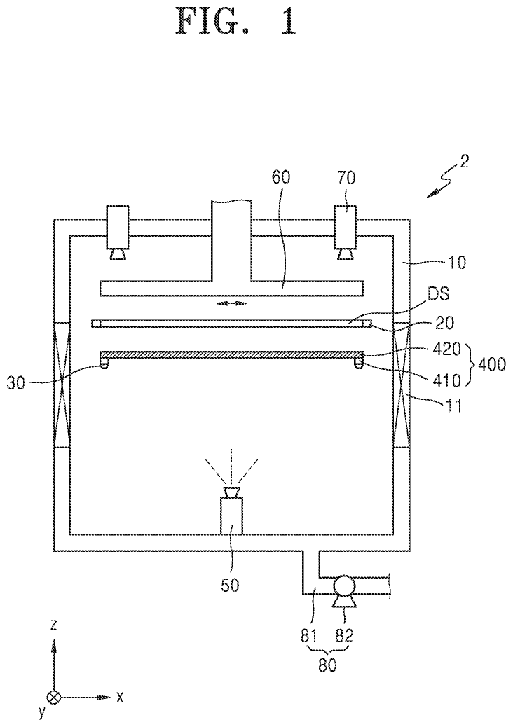

FIG. 1 is a cross-sectional view of an apparatus for manufacturing a display apparatus according to an embodiment.

An apparatus 2 for manufacturing a display apparatus may include a chamber 10, a first support portion 20, a second support portion 30, a mask assembly 400, a deposition source 50, a magnetic force portion 60, a vision portion 70, and a pressure control portion 80.

The chamber 10 may have a space formed therein, in which a display substrate DS and the mask assembly 400 may be accommodated. A portion of the chamber 10 may be formed to be open, and a gate valve 11 may be provided in the open portion of the chamber 10. In such an embodiment, the open portion of the chamber 10 may be open or closed depending on the operation of the gate valve 11.

The display substrate DS may be a display substrate DS in a process of manufacturing a display apparatus in which at least one of an organic layer, an inorganic layer, or a metal layer is deposited on a substrate 100, to be described below. Alternatively, the display substrate DS may be the substrate 100 on which none of the organic layer, the inorganic layer, and the metal layer are deposited.

The first support portion 20 may support the display substrate DS. The first support portion 20 may have a plate shape fixed in the chamber 10. In another embodiment, the first support portion 20 may be where the display substrate DS is placed and may be provided in the form of a shuttle configured for linear motion inside the chamber 10. In another embodiment, the first support portion 20 may include an electrostatic chuck or an adhesive chuck that is fixed to the chamber 10 or located in the chamber 10 and configured to be movable in the chamber 10.

The second support portion 30 may support the mask assembly 400. The second support portion 30 may be located in the chamber 10. The second support portion 30 may be configured for fine adjustment of the position of the mask assembly 400. For example, the second support portion 30 may include a separate driving portion (e.g., a separate driver), an alignment unit, and the like to move the mask assembly 400 in various directions.

In another embodiment, the second support portion 30 may be provided in the form of a shuttle. In such an embodiment, the mask assembly 400 is placed on the second support portion 30, and the second support portion 30 may transfer the mask assembly 400. For example, the second support portion 30 may move to the outside of the chamber 10 and may enter the chamber 10 from the outside after the mask assembly 400 is placed thereon.

In some embodiments, the first support portion 20 and the second support portion 30 may be integrally formed. In such an embodiment, the first support portion and the second support portion 30 may each include a movable shuttle. The first support portion 20 and the second support portion 30 may include structures to fix the mask assembly 400 and the display substrate DS with the display substrate DS being placed on the mask assembly 400, and the first support portion 20 and the second support portion 30 are configured to linearly move the display substrate DS and the mask assembly 400 at the same time.

However, in the following description, for convenience of explanation, an embodiment in which the first support portion 20 and the second support portion 30 are separately formed at different positions in the chamber 10 is primarily described in detail.

The deposition source 50 may be located to face the mask assembly 400. The deposition source 50 may include a deposition material, and the deposition material may evaporate or sublimate when heat is applied to the deposition material. The deposition source 50 may be located in a fixed position in the chamber 10 or may be configured to move linearly in one direction in the chamber 10.

The mask assembly 400 may be located in the chamber 10. The mask assembly 400 may include a mask frame 410 and a mask sheet 420, which is described below in more detail. The deposition material may be deposited on the display substrate DS by passing through the mask assembly 400.

The magnetic force portion 60 may be located in the chamber 10 to face the display substrate DS and/or the mask assembly 400. In this state, the magnetic force portion 60 may apply a force (e.g., a magnetic form) to the mask assembly 400 in a direction toward the display substrate DS. For example, the magnetic force portion 60 may not only prevent the mask sheet 420 from sagging but may also ensure that the mask sheet 420 is adjacent to the display substrate DS. Furthermore, the magnetic force portion 60 may maintain a uniform distance between the mask sheet 420 and the display substrate DS.

The vision portion 70 is located in the chamber 10 and may be configured to capture images of the positions of the display substrate DS and the mask assembly 400. The vision portion 70 may include a camera for capturing images of the display substrate DS and the mask assembly 400. The positions of the display substrate DS and the mask assembly 400 may be identified based on the images captured by the vision portion 70, and thus, deformation of the mask assembly 400 may be checked. Furthermore, based on the images, the first support portion 20 may finely adjust the position of the display substrate DS, or the second support portion 30 may finely adjust the position of the mask assembly 400. However, in the following description, an embodiment in which the positions of the display substrate DS and the mask assembly 400 are aligned with each other by finely adjusting the position of the mask assembly 400 by using the second support portion 30 is primarily described in detail.

The pressure control portion 80 is connected to the chamber 10 and may control the pressure in the chamber 10. For example, the pressure control portion 80 may control the pressure in the chamber 10 to be the same as or similar to atmospheric pressure. Furthermore, the pressure control portion 80 may control the pressure in the chamber 10 to be in a vacuum state or substantially in a vacuum state.

The pressure control portion 80 may include a connection pipe 81 connected to the chamber 10 and a pump 82 provided on (or along) the connection pipe 81. According to the operation of the pump 82, external air may be introduced into the chamber 10 through the connection pipe 81 or the gas inside the chamber 10 may be guided to the outside through the connection pipe 81.

In a method of manufacturing a display apparatus by using the apparatus 2 described above, first, the display substrate DS may be prepared.

The pressure control portion 80 may maintain the inside of the chamber 10 to be at or about atmospheric pressure, and as the gate valve 11 is operated, the open portion of the chamber 10 may be opened.

Then, the display substrate DS may be loaded from the outside of the chamber 10 into the inside thereof. The display substrate DS may be loaded into the chamber 10 by various suitable methods. For example, the display substrate DS may be loaded from the outside of the chamber 10 into the inside of the chamber 10 by a robot arm and the like located outside the chamber 10. In another embodiment, when the first support portion 20 is a shuttle, the first support portion 20 may be carried out from the inside of the chamber 10 to the outside of the chamber 10, the display substrate DS placed on the first support portion 20 by another robot arm and the like located outside the chamber 10, and the first support portion 20 be loaded from the outside of the chamber 10 into the chamber 10.

The mask assembly 400 may be located in the chamber 10 as described above. In another embodiment, the mask assembly 400 may be loaded from the outside of the chamber 10 into the chamber 10 in a manner that is the same as or similar to the display substrate DS.

When the display substrate DS is loaded into the chamber 10, the display substrate DS may be placed on the first support portion 20. In this state, the vision portion 70 may capture images of the positions of the display substrate DS and the mask assembly 400. The positions of the display substrate DS and the mask assembly 400 may be identified based on the images captured by the vision portion 70. The apparatus 2 for manufacturing a display apparatus includes a separate controller configured to identify the positions of the display substrate DS and the mask assembly 400.

When the positions of the display substrate DS and the mask assembly 400 are identified, the second support portion 30 may finely adjust the position of the mask assembly 400.

Then, when the deposition source 50 is operated, the deposition material may be supplied toward the mask assembly 400, and the deposition material having passed through a plurality of pattern openings (e.g., pattern holes) in the mask sheet 420 may be deposited on the display substrate DS. In this state, the deposition source 50 may move parallel to the display substrate DS and the mask assembly 400, or the display substrate DS and the mask assembly 400 may move parallel to the deposition source 50. For example, the deposition source 50 may move relative to the display substrate DS and the mask assembly 400. Then, the pump 82 sucks the gas from inside the chamber 10 and discharges it to the outside so that the pressure in the chamber 10 may be maintained at or about a vacuum state.

As described above, the deposition material supplied from the deposition source 50 passes through the mask assembly 400 to be deposited on the display substrate DS, and thus, at least one of a plurality of layers, for example, an organic layer, an inorganic layer, and a metal layer, to be stacked on a display apparatus to be described below may be formed.

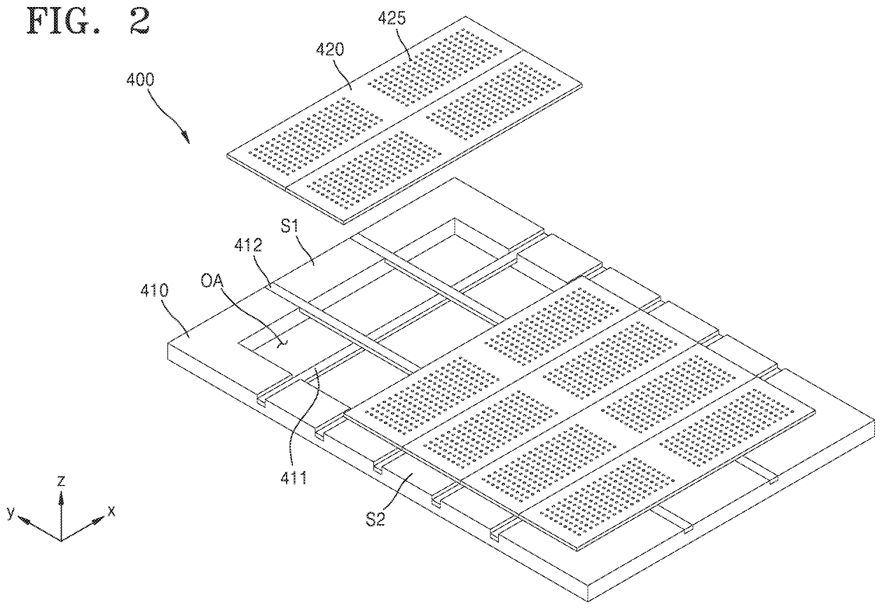

FIG. 2 is a schematic perspective view of a mask assembly according to an embodiment and shows a mask assembly which may be used in the apparatus for manufacturing a display apparatus.

Referring to FIG. 2, the mask assembly 400 may include the mask frame 410 and the mask sheet 420.

The mask frame 410 may be formed by connecting a plurality of sides and may have (e.g., the sides may form) an opening area OA defined by the plurality of sides. For example, the opening area OA may be formed by (e.g., may be surrounded in a plan view by) the plurality of sides, and the opening area OA may extend through the center of the mask frame 410.

A shielding stick 411 extending in a first direction, for example, an x direction in FIG. 2, may be located across the inside of the mask frame 410, that is, the opening area OA. Grooves for accommodating both end portions of the shielding stick 411 may be located (or formed) in the mask frame 410. The shielding stick 411 may be arranged in the grooves in the mask frame 410 and located between a plurality of mask frames 410 to shield a deposition material from passing between two adjacent mask frames 410. The shielding stick 411 may include a plurality of shielding sticks, ones of which may be spaced apart from each other in a second direction, for example, a y direction in FIG. 2, and arranged parallel to each other.

In addition, a support stick 412 extending in the second direction, for example, the y direction in FIG. 2, may be located across the inside of the mask frame 410, that is, across the opening area OA. The support stick 412 crosses the shielding stick 411 in the opening area OA and may be arranged on the shielding stick 411. Grooves for accommodating both end portions of the support stick 412 may be located in (or formed in) the mask frame 410. The support stick 412 may prevent sagging of the mask sheet 420 by supporting the mask sheet 420 in the opening area OA.

The mask frame 410 may be a rectangular frame in an embodiment. However, the shape of the mask frame 410 is not limited thereto, and the mask frame 410 may have various types of polygonal shapes. In the following description, for convenience of explanation, an embodiment in which the mask frame 410 has a quadrangular shape (e.g., is a quadrangular frame) is primarily described.

When the mask frame 410 is a quadrangular frame, the plurality of sides thereof may include a first side S1 extending in the first direction (e.g., the x direction in FIG. 2) and a second side S2 extending in the second direction (e.g., the y direction in FIG. 2) that crosses the first direction. The first side S1 is provided in a pair to face each other, and the second side S2 is provided in a pair to face each other. The first side S1 and the second side S2 may be connected to each other. In an embodiment, the first side S1 may be a short side, and the second side S2 may be a long side. However, the present disclosure is not limited thereto, and the first side S1 may be a long side and the second side S2 may be a short side, or the lengths of the first side S1 and the second side S2 may be the same. In the following description, for convenience of explanation, an embodiment in which the first side S1 is a short side and the second side S2 is a long side is primarily described.

The mask sheet 420 may be provided, in a tensioned state, on the mask frame 410. The opening area OA at the center of the mask frame 410 may be covered by the mask sheet 420. In an embodiment, the mask sheet 420 may include at least one mask sheet, and in an embodiment in which the mask sheet 420 includes at least two mask sheets, the mask sheets 420 may be located on the mask frame 410 to be parallel to each other. For example, the mask sheets 420 may be arranged in parallel in the second direction (e.g., the y direction in FIG. 2). Each of the mask sheets 420 may have a shape extending long in the first direction (e.g., the x direction in FIG. 2). Both end portions of each of the mask sheets 420 may be fixed to the mask frame 410 by, for example, welding.

The mask sheet 420 may include at least one pattern hole (e.g., one pattern opening) 425. The pattern hole 425 may be a through-hole formed to allow a deposition material to pass through the mask sheet 420. The deposition material, having passed through the mask sheet 420, may be deposited on the display substrate DS.

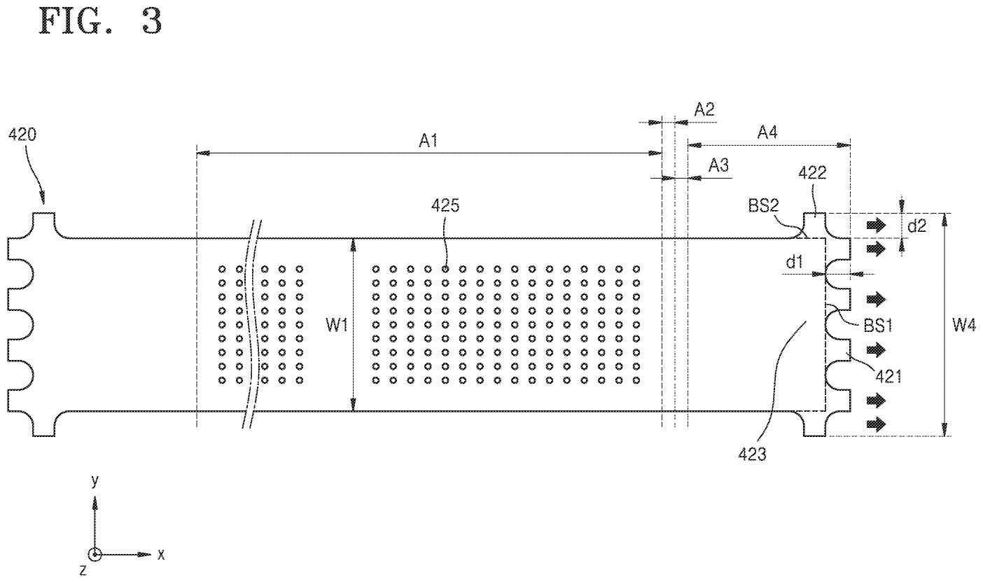

FIG. 3 is a schematic plan view of a mask sheet according to an embodiment. The mask sheet 420 may be a mask sheet provided in the mask assembly 400, and FIG. 3 illustrates a state before the mask sheet 420 is tensile-welded (e.g., is welded in a tensile state) to the mask frame 410 and cut off (or trimmed).

Referring to FIG. 3, the mask sheet 420 may have a shape extending long in (e.g., primarily extending in) a first direction (e.g., an x direction in FIG. 3) as described above. In an embodiment, the mask sheet 420 may have a deposition area A1, a welding area A2, a cutting area A3, and a clamping area A4. In an embodiment, the mask sheet 420 may have a shape in which both end portions thereof are symmetrical to each other in the first direction, and in the following description, for convenience of explanation, one end portion, that is, an end portion at the side in the x direction in FIG. 3, is primarily described.

The deposition area A1 is an area through which a deposition material may pass to be deposited on the display substrate DS (see, e.g., FIG. 1) and is where the pattern hole 425 may be located. The pattern hole 425 is formed in a pattern corresponding to a deposition pattern to be formed on the display substrate DS, and for example, may be formed in units of a plurality of cells to enable deposition on one or more display substrates DS.

The welding area A2 may be located at both end portions of the deposition area A1 in the first direction (e.g., the x direction in FIG. 3). The welding area A2 may be an area in which the mask sheet 420 is to be welded to the mask frame 410 to be fixed to the mask frame 410 after the mask sheet 420 is tensioned via the clamping area A4. In an embodiment, the mask sheet 420 may be welded to the mask frame 410 in the welding area A2 by a laser spot welding method.

The clamping area A4 may be located on a side (e.g., the side in the x direction in FIG. 3) opposite to a side facing the deposition area A1 from the welding area A2. In other words, clamping areas A4 may be located (or spaced) apart from each other in the first direction (e.g., the x direction in FIG. 3) so that the deposition area A1 is located therebetween. For example, the welding area A2 may be located between the deposition area A1 and the clamping area A4.

The clamping area A4 is an area grasped by a clamping apparatus to tension the mask sheet 420 and may be removed (e.g., may be cut off or trimmed) after the mask sheet 420 is welded to the mask frame 410. To this end, the cutting area A3 may be located between the welding area A2 and the clamping area A4. After the mask sheet 420 is tensioned and welded to the mask frame 410 in the welding area A2, the mask sheet 420 may be cut off in the cutting area A3 so that the clamping area A4 may be removed.

In an embodiment, the clamping area A4 may include a body portion 423, a first clamping portion 421, and a second clamping portion 422.

The body portion 423 may be connected to (e.g., may extend from) the cutting area A3, and the first clamping portion 421 and the second clamping portion 422 may be connected to each other to protrude from the body portion 423. The body portion 423 may have a first side BS1 spaced apart from the welding area A2 and/or the cutting area A3 in the first direction (e.g., the x direction in FIG. 3). The first side BS1 may extend in a second direction (e.g., a y direction in FIG. 3) crossing the first direction. A second side BS2 may be connected to each of both sides of the first side BS1. The second side BS2 may extend in, for example, the first direction, to cross the extension direction of the first side BS1.

The first clamping portion 421 may protrude from the first side BS1. In an embodiment, the first clamping portion 421 may protrude from the first side BS1 in the first direction (e.g., the x direction in FIG. 3) that is the longitudinal direction of the mask sheet 420. Here, the protrusion direction of the first clamping portion 421 may be a direction in which the center line of the width of the first clamping portion 421 faces.

The first clamping portion 421 may include at least one first clamping portion. For example, in the embodiment shown in FIG. 3, the first clamping portion 421 includes four first clamping portions, but the present disclosure is not limited thereto. When the first clamping portion 421 includes a plurality of first clamping portions, the first clamping portions 421 may be connected to each other in a rounded manner. For example, a portion of the first clamping portion 421 that initially protruding from the first side BS1 may be formed to be rounded. Accordingly, when each of the first clamping portions 421 is grasped and tensioned, the concentration of stress between the first clamping portions 421 may be reduced.

The second clamping portion 422 may protrude from the second side BS2. In an embodiment, the second clamping portion 422 may protrude from the second side BS2 in the second direction, that is, the width direction of the mask sheet 420. For example, the protrusion direction of the second clamping portion 422 may be a direction crossing the protrusion direction of the first clamping portion 421, for example, a direction perpendicular to the protrusion direction of the first clamping portion 421. The second clamping portion 422 protrudes in the second direction, and thus, a maximum (or greatest) width W4 of the clamping area A4 may be greater than a maximum (or greatest) width W1 of the deposition area A1 in a plan view.

In an embodiment, the second clamping portion 422 may be connected to an adjacent first clamping portion 421 in a rounded manner. For example, a portion of the second clamping portion 422 that initially protruding from the second side BS2 may be formed to be rounded. Accordingly, when the second clamping portion 422 is grasped and tensioned, the concentration of stress between the second clamping portion 422 and the first clamping portion 421 may be reduced.

Furthermore, in an embodiment, a protrusion length d2 of the second clamping portion 422 and a protrusion length d1 of the first clamping portion 421 may be the same as shown in FIG. 3, which may further facilitate design and manufacture of the mask sheet 420. However, the present disclosure is not necessarily limited thereto, and in some embodiments, the protrusion length d2 of the second clamping portion 422 may be greater than the protrusion length d1 of the first clamping portion 421.

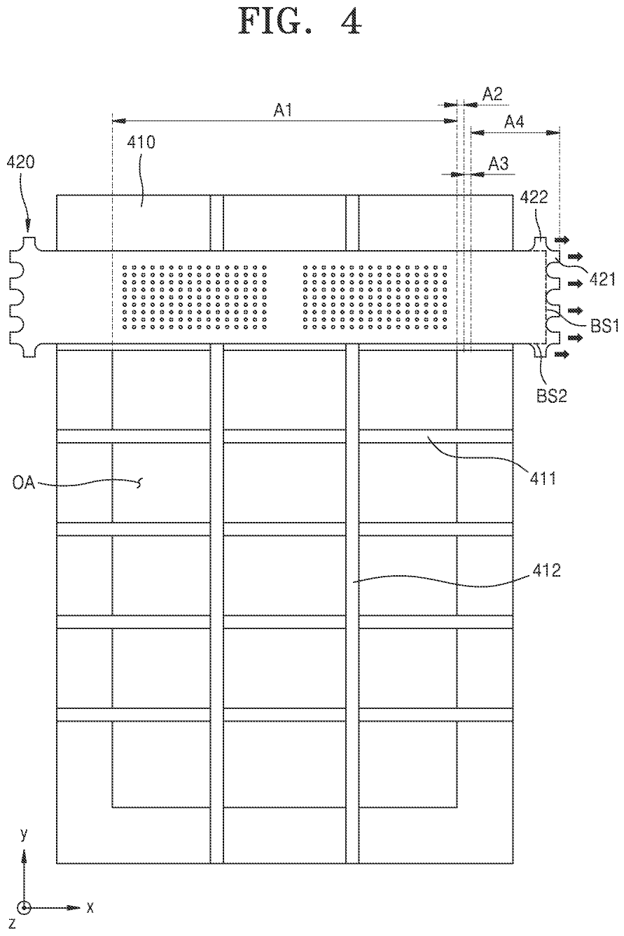

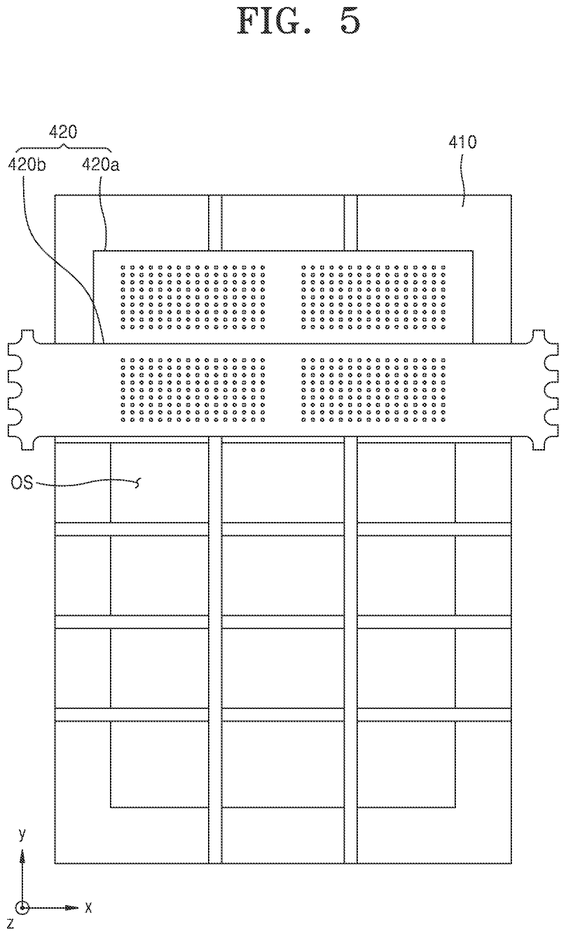

FIGS. 4 and 5 are schematic diagrams of a method of manufacturing a display apparatus according to an embodiment.

In the following description, a method of manufacturing a display apparatus by using the mask sheet 420 is described. Referring to FIG. 4, the mask sheet 420 may be used in the apparatus 2 for manufacturing a display apparatus (see, e.g., FIG. 1) for manufacturing a display apparatus. In the following description, for convenience of explanation, an end portion of the mask sheet 420 at the side in the x direction in FIG. 4 is primarily described, but the same process may be performed symmetrically for an end portion at the side in a −x direction in FIG. 4.

The mask sheet 420 may be located to cover (e.g., may be arranged over) the opening area OA of the mask frame 410. In this state, the deposition area A1 of the mask sheet 420 may be located to correspond to the opening area OA. The welding area A2, the cutting area A3, and the clamping area A4 may be placed (or arranged) outside the opening area OA of the mask frame 410 and may be supported by the mask frame 410.

Next, the first clamping portion 421 and the second clamping portion 422 may be clamped by a clamping apparatus, and the mask sheet 420 may be tensioned in a first direction (e.g., the x direction in FIG. 4). The first direction in which the mask sheet 420 is tensioned may correspond to the longitudinal direction of the mask sheet 420.

As such, waves formed in the mask sheet 420 due to the tensioning may be improved (or reduced) by the second clamping portion 422 protruding from the second side BS2. For example, the first clamping portion 421 protruding in the first direction (e.g., the x direction in FIG. 4) is tensioned in the first direction, that is, the longitudinal direction of the mask sheet 420, and thus, waves may occur in the mask sheet 420 in the width direction (e.g., a y direction in FIG. 4). In an embodiment, the second clamping portion 422 protrudes from the second side BS2 in a second direction (e.g., the y direction in FIG. 4), and the clamping apparatus may tension the second clamping portion 422 in the first direction while grasping the second clamping portion 422. Thus, a tensile force acting on the second side BS2 may be applied in a direction between the first direction and the second direction and may smooth out waves formed in the mask sheet 420. Waves in the mask sheet 420 reduce adhesion to the display substrate DS during a deposition process, thereby causing deposition defects, such as shadows. Therefore, the improvement (or reduction) of waves in the mask sheet 420 may improve deposition quality of a display apparatus.

Furthermore, the described embodiment may be more efficient than tensioning the mask sheet 420 in all directions in a general deposition process. In a general deposition process, clamping apparatuses for tensioning are designed and set to tension in the first direction, and thus, no other apparatus or no other design is necessary to tension the second clamping portion 422 in the first direction. Furthermore, the second clamping portion 422 is not located in the deposition area A1 in which the pattern holes 425 are finely formed, and thus, a high degree of optimization, which is required when the deposition area A1 is tensioned in the width direction, may not be required.

The mask sheet 420 may be welded, in a tensioned state, to the mask frame 410 in the welding area A2. The welding area A2 may be located adjacent to the opening area OA in the mask frame 410. In an embodiment, the mask sheet 420 may be welded to the mask frame 410 by a laser spot welding method.

Next, the mask sheet 420 is cut off (e.g., is trimmed) in the cutting area A3 to remove the clamping area A4. As such, the clamping area A4 (e.g., the first clamping portion 421 and the second clamping portion 422) may be removed after tensile-welding so that both end portions of the mask sheet 420 may be located inside the perimeter of the mask frame 410 as shown in, for example, FIG. 2. Furthermore, the second clamping portion 422 is located outside the welding area A2 (that is, at the side of the x direction in FIG. 4) and is removed, and thus, when a plurality of mask sheets 420 are located, interference with between adjacent mask sheet 420 may be prevented.

Referring to FIG. 5, when a plurality of mask sheets 420 are arranged, in an embodiment, the mask sheet 420 may be divided into a first mask sheet 420a and a second mask sheet 420b. After the first mask sheet 420a is tensile-welded and cut off, the second mask sheet 420b may be located parallel to the first mask sheet 420a. The second mask sheet 420b may be located parallel to the first mask sheet 420a in a direction (e.g., a y direction in FIG. 5) crossing the longitudinal direction (e.g., an x direction in FIG. 5) of the first mask sheet 420a. Next, similar to the first mask sheet 420a, the second mask sheet 420b may be tensioned, welded, and cut off.

The mask assembly 400, manufactured as described above, may be completed as shown in FIG. 2, and the mask assembly 400 may be used for deposition of a display apparatus as described above.

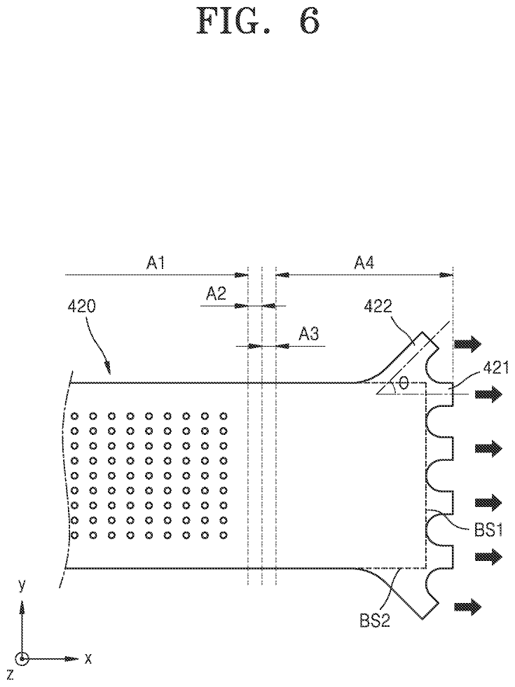

FIG. 6 is a schematic plan view of a mask sheet according to another embodiment. The mask sheet 420 shown in FIG. 6 is similar to the mask sheet 420 described above, and thus, differences therebetween are primarily described below.

Referring to FIG. 6, the first clamping portion 421 may protrude from the first side BS1 in the first direction, and the second clamping portion 422 may protrude from the second side BS2 in a third direction between the first direction and the second direction. The third direction may have an inclination angle θ with respect to the first direction, that is, the protrusion direction of the first clamping portion 421. In an embodiment, the inclination angle θ with respect to the first direction may be greater than about 0° and less than about 90°, and for example, the inclination angle θ may be about 45° as shown in FIG. 4. Also, in another embodiment, the second clamping portion 422 may protrude from the second side BS2 in a fourth direction. The fourth direction may have an inclination angle that is greater than about 90° and less than about 180° with respect to the first direction, that is, the protrusion direction of the first clamping portion 421. In the following description, for convenience of explanation, an embodiment in which the second clamping portion 422 protrudes in the third direction is primarily described.

As described above with reference to FIGS. 4 and 5, the mask sheet 420 may be located on the mask sheet 420 and tensioned in a first direction (e.g., an x direction in FIG. 6). As described above, the first clamping portion 421 and the second clamping portion 422 may be tensioned in the first direction. For example, the third direction, that is, the protrusion direction of the second clamping portion 422, crosses the first direction in which the second clamping portion 422 is tensioned, and thus, a tensile force acting on the second side BS2 may be applied in a direction between the protrusion direction of the second clamping portion 422 and a direction in which the second clamping portion 422 is tensioned by the clamping apparatus. Accordingly, as described above, waves in the mask sheet 420 in the width direction may be improved (or reduced).

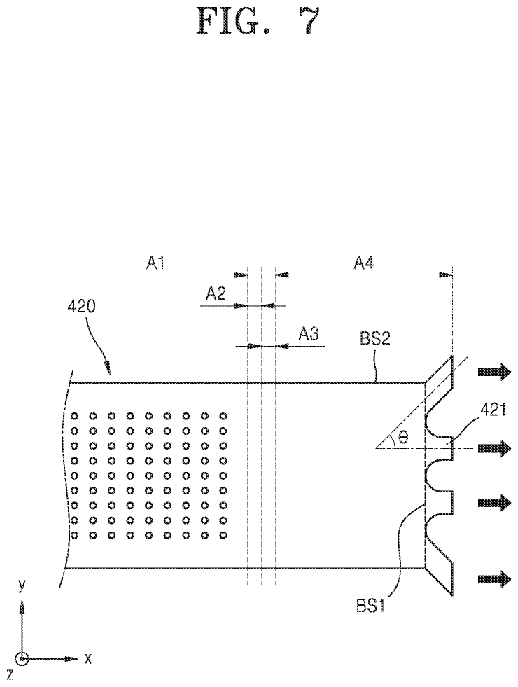

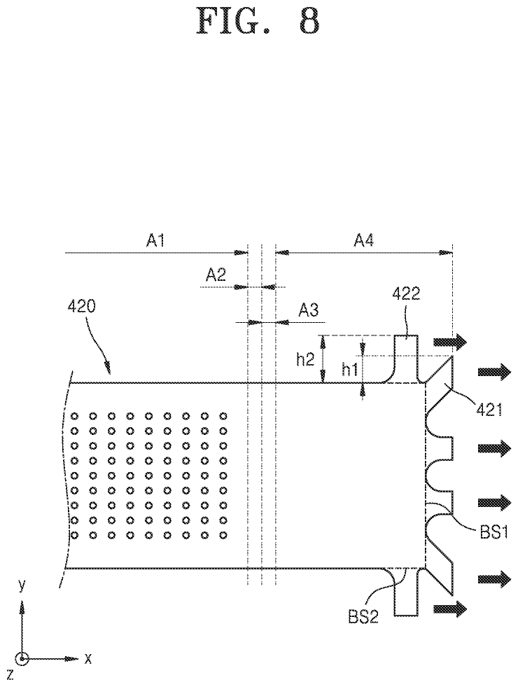

FIGS. 7 and 8 are schematic diagrams of a mask sheet according to another embodiment. The mask sheet 420 shown in FIGS. 7 and 8 is similar to the mask sheet 420 described above, and thus, differences therebetween are primarily described in the following descriptions.

Referring to FIG. 7, the first clamping portion 421 may include a plurality of first clamping portions. For example, the first clamping portions 421 may protrude from the first side BS1 and may be extend parallel to each other in an extension direction (e.g., a y direction in FIG. 7) of the first side BS1. While some of the first clamping portions 421 may protrude in the first direction, others may protrude in the third direction crossing the first direction. For example, first clamping portions 421 except for two first clamping portions 421 adjacent to both end portions (or opposite end portions) of the first side BS1 from among the first clamping portions 421 may protrude in the first direction, for example, the longitudinal direction (e.g., an x direction in FIG. 7) of the mask sheet 420. Protrusion directions of the two first clamping portions 421 adjacent to both end portions of the first side BS1 from among the first clamping portions 421 may each have an inclination angle θ toward the outside to cross the protrusion direction of one of the other first clamping portions 421.

In an embodiment, the inclination angle θ with respect to the first direction may be greater than about 0° and less than about 90°. For example, the inclination angle θ may be about 45° as shown in FIG. 4.

Accordingly, as described above, when the first clamping portion 421 is tensioned in the first direction, waves in the mask sheet 420 in the width direction may be improved (or reduced). Accordingly, even in embodiment in which the second clamping portion 422 is omitted, the embodiment is not limited thereto and the second clamping portion 422 may protrude as shown in FIG. 8.

Referring to FIG. 8, compared to the mask sheet 420 shown in FIG. 7, the second clamping portion 422 may protrude from the second side BS2. The second clamping portion 422 may protrude in a second direction (e.g., a y direction in FIG. 8), that is, the width direction of the mask sheet 420, as shown in FIG. 8, but the present disclosure is not limited thereto. In other embodiments, the second clamping portion 422 may protrude in the third direction between the first direction and the second direction as shown in FIG. 6. In the following description, for convenience of explanation, an embodiment in which the second clamping portion 422 protrudes in the second direction as shown in FIG. 8 is primarily described.

A length h1 of the first clamping portion 421 that is adjacent to one of both end portions of the first side BS1 from among the first clamping portions 421 in the second direction, may be less than a length h2 of the second clamping portion 422 in the second direction. Accordingly, the clamping apparatus may grasp the first clamping portion 421 and the second clamping portion 422 without interference.

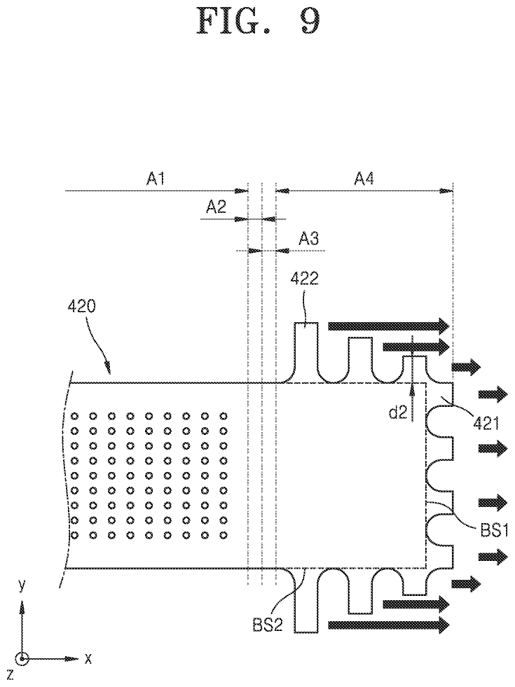

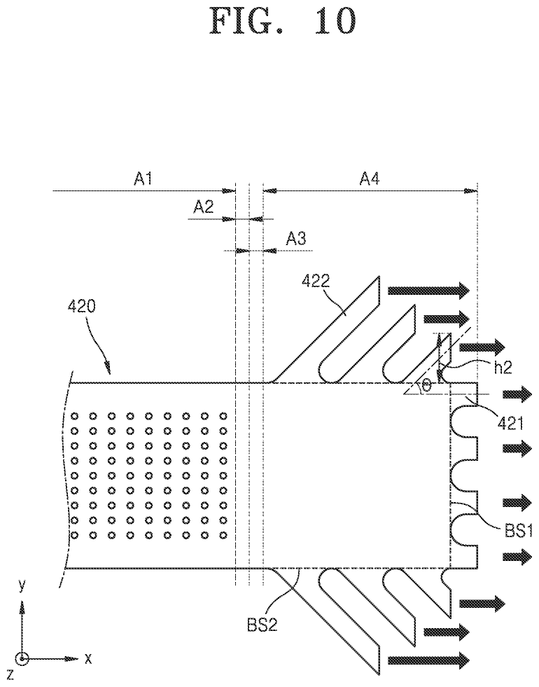

FIGS. 9 and 10 are schematic plan views of the mask sheet 420 according to another embodiment. The mask sheet 420 shown in FIGS. 9 and 10 is similar to the mask sheet 420 described above, and thus, differences therebetween are primarily described in the following description.

Referring to FIG. 9, the second clamping portion 422 may protrude from the second side BS2. In an embodiment, the second clamping portion 422 may protrude in a second direction (e.g., a y direction in FIG. 9). The second clamping portion 422 may include a plurality of second clamping portions along (e.g., adjacent to each other along) the second side BS2 in a first direction (e.g., an x direction in FIG. 9). For example, the second clamping portion 422 may include three second clamping portions on one side as shown in FIG. 9, but the present disclosure is not limited thereto. In another embodiment, the second clamping portion 422 may include at least two second clamping portions. In the following description, for convenience of explanation, an embodiment in which the second clamping portion 422 includes three second clamping portions on one side is primarily described.

In an embodiment, the second clamping portions 422 may protrude parallel to each other, and protrusion lengths d2 of the second clamping portions 422 may be different from each other. For example, a protrusion length d2 of a second clamping portion 422 located nearest to an end portion of the mask sheet 420 in the first direction from among the second clamping portions 422 may be the smallest. In an embodiment, the differences in protrusion lengths d2 between each two adjacent second clamping portions 422 may be the same. As such, as the protrusion length d2 is formed, the clamping apparatus may grasp the second clamping portions 422 and tension the second clamping portions 422 in the first direction without interference. Accordingly, waves in the mask sheet 420 in the width direction may be improved (or reduced).

Referring to FIG. 10, the second clamping portion 422 may include a plurality of second clamping portions along the second side BS2 in a first direction (e.g., an x direction of FIG. 10). In an embodiment, as described with reference to FIG. 6, each of the second clamping portions 422 may protrude in the third direction between the first direction, that is, the longitudinal direction of the mask sheet 420, and the second direction, that is, the width direction of the mask sheet 420. The second clamping portions 422 may protrude parallel to each other. For example, the protrusion direction of the second clamping portion 422 may have an inclination angle θ with respect to the first direction (e.g., the x direction in FIG. 10). In an embodiment, the inclination angle θ with respect to the first direction may be greater than about 0° and less than about 90°, and may be, in one embodiment, about 45° as shown in FIG. 4. In another embodiment, the second clamping portions 422 may protrude from the second side BS2 in a fourth direction. The fourth direction may have an inclination angle that is greater than about 90° and less than about 180° with respect to the first direction. In the following description, for convenience of explanation, an embodiment in which the second clamping portions 422 protrude in the third direction is primarily described.

Lengths h2 of the second clamping portions 422 in the second direction may be different from each other. For example, a length h2 of a second clamping portion 422 located nearest to an end portion of the mask sheet 420 in the first direction from among the second clamping portions 422 in the second direction, may be the smallest. In an embodiment, differences in lengths h2 in the second direction between each two adjacent second clamping portions 422 may be the same. As such, due to the different lengths h2 in the second direction, the clamping apparatus may grasp the second clamping portions 422 and tension the second clamping portions 422 in the first direction without interference. Accordingly, waves in the mask sheet 420 in the width direction may be improved (or reduced).

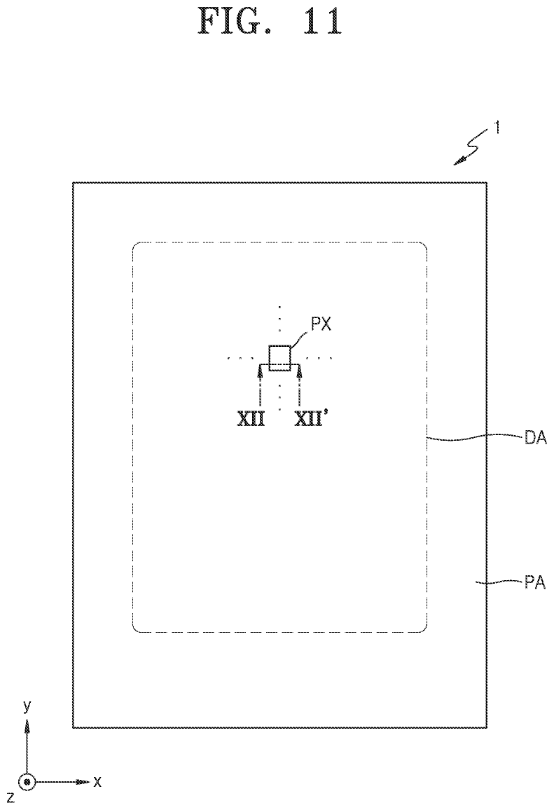

FIG. 11 is a schematic plan view of a display apparatus manufactured by a method of manufacturing a display apparatus according to an embodiment.

Referring to FIG. 11, a display apparatus 1 manufactured according to an embodiment may have a display area DA and a peripheral area PA located outside the display area DA. The display apparatus 1 may provide an image through an array of a plurality of pixels PX two-dimensionally arranged in the display area DA.

The peripheral area PA is an area that does not provide (or emit) an image and may entirely or partially surround, in a plan view, the display area DA. Drivers and the like for providing electrical signals or power to a pixel circuit corresponding to each of the pixels PX may be located in the peripheral area PA. A pad, that is, an area to which electronic devices, printed circuit boards, and the like may be electrically connected, may be located in the peripheral area PA.

In the following description, although the display apparatus 1 is described as including an organic light-emitting diode (OLED) as a light-emitting element, the present disclosure is not limited thereto. In another embodiment, the display apparatus 1 may include a light-emitting display including an inorganic light-emitting diode, that is, an inorganic light-emitting display. The inorganic light-emitting diode may include a PN diode including materials based on an inorganic material semiconductor. When a voltage is supplied to a PN junction diode in a forward direction, holes and electrons are injected, and energy generated due to recombination of the holes and the electrons is converted to light energy so that light of a certain color may be emitted. The inorganic light-emitting diode described above may have a width in a range of tens to hundreds of micrometers, and in some embodiments, the inorganic light-emitting diode may be referred to as a micro LED. In another embodiment, the display apparatus 1 may include a quantum-dot light-emitting display.

The display apparatus 1 may be used as a display screen of various products, for example, not only portable electronic apparatuses, such as mobile phones, smartphones, tablet personal computers (PCs), mobile communication terminals, electronic organizers, electronic books, portable multimedia players (PMPs), navigation devices, ultra mobile PCs (UMPCs), and the like, but also televisions, notebook computers, monitors, billboards, Internet of Things (IoT) devices, and the like. Furthermore, the display apparatus 1 according to an embodiment may be used in wearable devices, such as smart watches, watch phones, glasses-type displays, head mounted displays (HMDs), and the like. Furthermore, the display apparatus 1, according to an embodiment, may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment for a rear seat of vehicles.

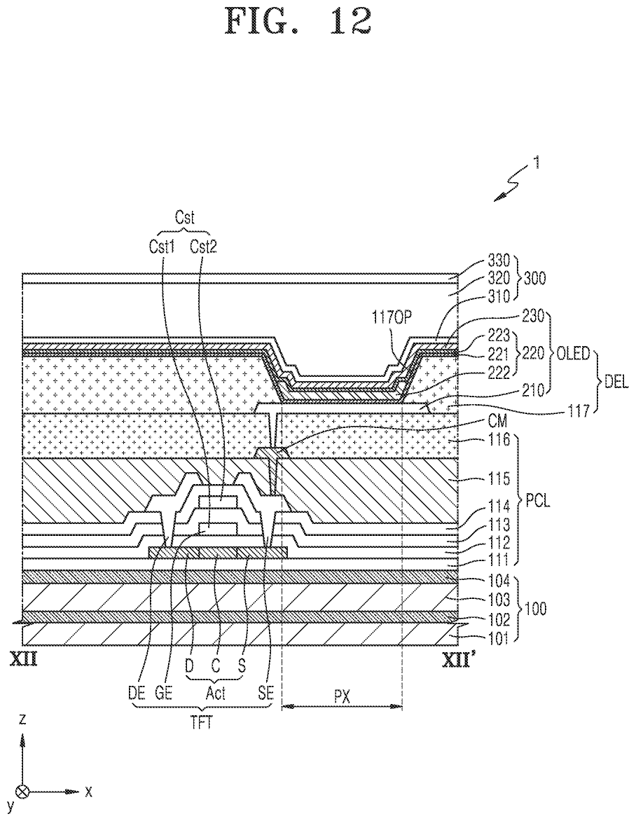

FIG. 12 is a schematic cross-sectional view of the display apparatus 1 taken along the line XII-XII′ of FIG. 11.

Referring to FIG. 12, the display apparatus 1 may include a stack structure of the substrate 100, a pixel circuit layer PCL, a display element layer DEL, and an encapsulation layer 300. The display substrate DS (see, e.g., FIG. 1) may be obtained (or formed) by stacking at least one of the pixel circuit layer PCL, the display element layer DEL, and the encapsulation layer 300 on, for example, the substrate 100 that is in the process of manufacturing the display apparatus 1.

The substrate 100 may having a multilayer structure including a base layer including polymer resin and an inorganic layer. For example, the substrate 100 may include a base layer including polymer resin and a barrier layer, that is, an inorganic insulating layer. For example, the substrate 100 may include a first base layer 101, a first barrier layer 102, a second base layer 103, and a second barrier layer 104, which are sequentially stacked. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), cellulose acetate propionate (CAP), or/and the like. The first barrier layer 102 and the second barrier layer 104 may include an inorganic insulating material, such as a silicon oxide, a silicon oxynitride, and/or a silicon nitride. The substrate 100 may be flexible.

The pixel circuit layer PCL is located on the substrate 100. FIG. 12 illustrates an embodiment in which the pixel circuit layer PCL includes a thin-film transistor TFT, and a buffer layer 111, a first gate insulating layer 112, a second gate insulating layer 113, an interlayer insulating layer 114, a first planarization insulating layer 115, and a second planarization insulating layer 116, which are located below or/and above constituent elements of the thin-film transistor TFT.

The buffer layer 111 may reduce or block infiltration of foreign materials, such as moisture or external air, from under the substrate 100, and may provide a planarized surface on the substrate 100. The buffer layer 111 may include an inorganic insulating material, such as a silicon oxide, a silicon oxynitride, and a silicon nitride, and may have a single layer or multilayer structure including the above-described materials.

The thin-film transistor TFT on the buffer layer 111 may include a semiconductor layer Act, and the semiconductor layer Act may include polysilicon. In other embodiments, the semiconductor layer Act may include amorphous silicon, an oxide semiconductor, an organic semiconductor, or the like. The semiconductor layer Act may have a channel region C and a drain region D and a source region S located at opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), titanium (Ti), and the like, and may have a multilayer or single layer structure including the above materials.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. ZnO may include ZnO and/or ZnO₂.

The second gate insulating layer 113 may cover the gate electrode GE. The second gate insulating layer 113, similar to the first gate insulating layer 112, may include an inorganic insulating material, such as SiO₂, SiNₓ, SiON, Al₂O₃, TiO₂, Ta₂O₅, HfO₂, or ZnOₓ. ZnO may include ZnO and/or ZnO₂.

An upper electrode Cst2 of a storage capacitor Cst may be located on the second gate insulating layer 113. The upper electrode Cst2 may overlap the gate electrode GE thereunder. The gate electrode GE and the upper electrode Cst2 overlapping each other with the second gate insulating layer 113 therebetween may form the storage capacitor Cst. For example, the gate electrode GE may act as a lower electrode Cst1 of the storage capacitor Cst.

As such, the storage capacitor Cst and the thin-film transistor TFT may overlap each other. In some embodiments, the storage capacitor Cst may not overlap the thin-film transistor TFT.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may have a single layer or multilayer structure including the above-described materials.

The interlayer insulating layer 114 may cover the upper electrode Cst2. The interlayer insulating layer 114 may include SiO₂, SiNₓ, SiON, Al₂O₃, TiO₂, Ta₂O₅, HfO₂, or ZnOₓ, and the like. ZnO may include ZnO and/or ZnO₂. The interlayer insulating layer 114 may have a single layer or multilayer structure including the above-described inorganic insulating material.

A drain electrode DE and a source electrode SE may each be located on the interlayer insulating layer 114. The drain electrode DE and the source electrode SE may be respectively connected to the drain region D and the source region S through contact holes (e.g., contact openings) formed in the insulating layers thereunder. The drain electrode DE and the source electrode SE may include a material exhibiting excellent conductivity. The drain electrode DE and the source electrode SE may include a conductive material including Mo, Al, Cu, Ti, and the like, and may have a multilayer or single layer structure including the above material. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material, including general purpose polymers, such as polymethylmethacrylate (PMMA) or polystyrene (PS), polymer derivatives having a phenolic group, acrylic polymers, imide-based polymers, aryl ether-based polymers, amide-based polymers, fluorine-based polymers, p-xylene-based polymers, vinyl alcohol-based polymers, and blends thereof.

The second planarization insulating layer 116 may be located on the first planarization insulating layer 115. The second planarization insulating layer 116 may include the same material as the first planarization insulating layer 115 and may include an organic insulating material, including general purpose polymers, such as PMMA or PS, polymer derivatives having a phenolic group, acrylic polymers, imide-based polymers, aryl ether-based polymers, amide-based polymers, fluorine-based polymers, p-xylene-based polymers, vinyl alcohol-based polymers, and blends thereof.

The display element layer DEL may be located on the pixel circuit layer PCL having the above-described structure. The display element layer DEL may include an organic light-emitting diode OLED as a display element (e.g., a light-emitting element), and the organic light-emitting diode OLED may include a stacked structure of a pixel electrode 210, an intermediate layer 220, and a common electrode 230. The organic light-emitting diode OLED may emit, for example, red, green, or blue light, or red, green, blue, or white light. The organic light-emitting diode OLED may emit light at a light-emitting area, and the light-emitting area may be defined to be a pixel PX.

The pixel electrode 210 of the organic light-emitting diode OLED may be electrically connected to the thin-film transistor TFT through contact holes (e.g., contact openings) formed in the second planarization insulating layer 116 and the first planarization insulating layer 115 and a contact metal CM located on the first planarization insulating layer 115.

The pixel electrode 210 may include a conductive oxide, such as an indium tin oxide (ITO), an indium zinc oxide (IZO), ZnO, an indium oxide (In₂O₃), an indium gallium oxide (IGO), or an aluminum zinc oxide (AZO). In another embodiment, the pixel electrode 210 may include a reflective film including Ag, Mg, Al, Pt, Pd, Au, Ni, Nd, Ir, Cr, or a compound thereof. In another embodiment, the pixel electrode 210 may further include a layer including ITO, IZO, ZnO, or In₂O₃ above/below the above-described reflective film.

A pixel-defining layer 117 having an opening 1170P that exposes a center portion of the pixel electrode 210 is located on the pixel electrode 210. The pixel-defining layer 117 may include an organic insulating material and/or an inorganic insulating material. The opening 1170P may define a light-emitting area where light from the organic light-emitting diode OLED is emitted. For example, the size/width of the opening 1170P may correspond to the size/width of the light-emitting area. Accordingly, the size and/or width of the pixel PX may depend on the size and/or width of the opening 1170P of the pixel-defining layer 117 corresponding to the pixel PX.

The intermediate layer 220 may include an emission layer 222 formed to correspond to the pixel electrode 210. The emission layer 222 may include a polymer or low molecular weight organic material that emits light of a certain color. In other embodiments, the emission layer 222 may include an inorganic light-emitting material or quantum dots.

In an embodiment, the intermediate layer 220 may include a first functional layer 221 and a second functional layer 223 which are respectively located below and above the emission layer 222. The first functional layer 221 may include, for example, a hole transport layer (HTL), or HTL and a hole injection layer (HIL). The second functional layer 223 that is located above the emission layer 222 may include an electron transport layer (ETL) and/or an electron injection layer (EIL). The first functional layer 221 and/or the second functional layer 223, similar to the common electrode 230 described below, may be a common layer that entirely covers the substrate 100.

The common electrode 230 is located on the pixel electrode 210 and may overlap the pixel electrode 210. The common electrode 230 may include a conductive material having a low work function. For example, the common electrode 230 may include a (semi-)transparent layer including Ag, Mg, Al, Pt, Pd, Au, Ni, Nd, Ir, Cr, lithium (Li), Ca, or an alloy thereof, and the like. In some embodiments, the common electrode 230 may further include a layer including ITO, IZO, ZnO or In₂O₃ on the (semi-)transparent layer including the above-described materials. The common electrode 230 may be integrally formed to entirely cover the substrate 100.

The encapsulation layer 300 may be located on the display element layer DEL and may cover the display element layer DEL. The encapsulation layer 300 includes at least one an inorganic encapsulation layer and at least one organic encapsulation layer, and FIG. 12 illustrates an embodiment in which the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials from among an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may have transparency.

A touch sensor layer may be located on the encapsulation layer 300, and an optical functional layer may be located on the touch sensor layer. The touch sensor layer may obtain coordinate information according to an external input, for example, a touch event. The optical functional layer may reduce reflectivity of light (e.g., external light) incident on a display apparatus from the outside and/or may improve the color purity of light emitted from the display apparatus. In an embodiment, the optical functional layer may include a retarder and/or a polarizer. The retarder may be of a film type or a liquid crystal coating type and may include a λ/2 (half wave) retarder and/or a λ/4 (quarter wave) retarder. The polarizer may also be of a film type or a liquid crystal coating type. The film type may include a stretchable synthetic resin film, and a liquid crystal coating type may include liquid crystals arranged in a certain array. The retarder and the polarizer may further include a protective film.

An adhesive member may be located between the touch electrode layer and the optical functional layer. The adhesive member may be a general adhesive that is well-known in the field of technology without limitation. For example, the adhesive member may be a pressure sensitive adhesive (PSA).

According to embodiments, deposition quality of a deposition material is improved by improving waves that may occur when a mask sheet is tensile-welded.

The embodiments described herein should be considered in a descriptive sense and not for purposes of limitation. Descriptions of features and/or aspects within each embodiment should typically be considered as available for other similar features and/or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A mask sheet having:
a deposition area;
clamping areas spaced apart from each other in a first direction with the deposition area therebetween; and
a welding area between each of the clamping areas and the deposition area,
wherein each of the clamping areas comprises:
a body portion having a first side spaced apart from the welding area in the first direction and a second side connected to each of both sides of the first side to cross the first direction;
a first clamping portion protruding from the first side; and
a second clamping portion protruding from the second side.

2. The mask sheet of claim 1, wherein a protrusion direction of the second clamping portion is perpendicular to a protrusion direction of the first clamping portion.

3. The mask sheet of claim 1, wherein a protrusion direction of the second clamping portion has an inclination greater than 0° and less than 90° with respect to a protrusion direction of the first clamping portion.

4. The mask sheet of claim 1, wherein, in a plan view, a maximum width of the mask sheet in the clamping areas is greater than a maximum width of the mask sheet in the deposition area.

5. The mask sheet of claim 1, wherein a protrusion length of the second clamping portion is equal to a protrusion length of the first clamping portion.

6. The mask sheet of claim 1, wherein the first clamping portion and the second clamping portion are connected to each other in a rounded manner.

7. The mask sheet of claim 1, wherein the first clamping portion comprises a plurality of first clamping portions arranged along the first side, and
wherein a protrusion direction of the first clamping portions adjacent to each of both end portions of the first side from among the first clamping portions has an inclination with respect to a protrusion direction of one of the other first clamping portions.

8. The mask sheet of claim 1, wherein the second clamping portion comprises a plurality of second clamping portions arranged along the second side, and
wherein protrusion lengths of the second clamping portions are different from each other.

9. The mask sheet of claim 8, wherein the protrusion length of respective ones of the second clamping portions increases the nearer each of the second clamping portions is to the welding area.

10. The mask sheet of claim 9, wherein differences in protrusion lengths between two adjacent ones of the second clamping portions from among the second clamping portions are constant.

11. The mask sheet of claim 8, wherein protrusion directions of the second clamping portions are identical to each other.

12. The mask sheet of claim 1, also has a cutting area between the welding area and the clamping area.

13. A method of manufacturing a display apparatus, the method comprising:
preparing a mask frame having an opening area;
arranging a mask sheet extending in a first direction and extending over the opening area in the mask frame;
tensioning the mask sheet in the first direction;
welding the mask sheet to the mask frame;
arranging a display substrate to face the mask sheet; and
allowing a deposition material supplied from a deposition source to pass through the mask sheet to be deposited on the display substrate,
wherein the mask sheet comprises:
a first clamping portion protruding from each of both end portions of the mask sheet in the first direction; and
a second clamping portion protruding in a direction crossing the first direction, and
wherein the tensioning of the mask sheet comprises tensioning the first clamping portion and the second clamping portion in the first direction.

14. The method of claim 13, wherein the arranging of the mask sheet comprises arranging the first clamping portion and the second clamping portion outside an area where the mask sheet is to be welded to the mask frame in directions of both end portions of the mask sheet.

15. The method of claim 13, wherein the tensioning of the mask sheet comprises tensioning the second clamping portion in a direction crossing a protrusion direction of the second clamping portion.

16. The method of claim 15, wherein the tensioning of the mask sheet comprises tensioning the second clamping portion in a direction perpendicular to the protrusion direction of the second clamping portion.

17. The method of claim 13, wherein the second clamping portion comprises a plurality of second clamping portions in the first direction, and
wherein protrusion lengths of the second clamping portions are different from each other.

18. The method of claim 17, wherein protrusion directions of the second clamping portions are identical to each other.

19. The method of claim 13, further comprising cutting both end portions of the mask sheet to remove the first clamping portion and the second clamping portion.

20. The method of claim 19, wherein the mask sheet comprises a first mask sheet and a second mask sheet, and
wherein the welding and cutting of the mask sheet comprises, after the first mask sheet is welded to the mask frame and both end portions of the first mask sheet are cut off, welding the second mask sheet to the mask frame and cutting both end portions of the second mask sheet.
